(19) United States
(12) Patent Application Publication
(10) Pub. No.: US 2005/0147262 A1
(43) Pub. Date: Jul. 7, 2005

(54) Method for decreasing the dynamic range of a signal and electronic circuit

(76) Inventor: Dirk Jeroen Breebaart, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/502,143

(22) PCT Filed: Dec. 20, 2002
(86) PCT No.: PCT/IB02/05674

(30) Foreign Application Priority Data
Jan. 24, 2002 (EP) 02075304.2

(51) Int. Cl. H03G 7/00; H04B 1/64

(52) U.S. Cl. 381/106; 333/14

(57) ABSTRACT

The invention relates to a method of decreasing the dynamic range of a signal comprising the steps of:—determining a property of the signal,—determining a limitation parameter based on the property of the signal,—limiting the signal by means of the limitation parameter,—clipping the limited signal.

### FIELD OF THE INVENTION

The present invention relates to the field of dynamic range compression, and more particularly to dynamic range compression of audio signals.

### BACKGROUND AND PRIOR ART

Dynamic range control (DRC) devices have been used for many years for a variety of purposes. One field of application of DRC devices in broadcasting for the protection of transmitters against overload. For this purpose it is necessary to modify the dynamic range of the broadcast signal because the channel has a defined peak limit at which server distortion on and overload can occur, and a lower limit determined by noise. Usually the dynamic range of the source material can be expected to be greater than that of the broadcast channel, and therefore some kind of gain control must be used to maximize the service area without overloading the transmitter.

A limiter is one such device which has been developed for specific broadcasting applications. It has also been used to prevent over-cutting in the preparation of audio discs and to control levels before analogue-to-digital conversion.

Another known device for dynamic range control is a compressor. A compressor is used to effect larger change to the dynamic range by being active over a wider range of input signal levels. For example, compressors have been used to match the relatively wide dynamic range of sound-program signals to the much narrower dynamic range of AM radio transmissions. A compressor can also be used to smooth out the variations in level caused than a vocalist moves towards an away from the microphone or to create special effects by altering the natural decay characteristic of an instrument such as a guitar.

A variety of digital methods for controlling the dynamic range of digitally coded audio signals is known from McNally, G. W., Dynamic range control of digital audio signals. J. Audio Eng. Soc., 32, 316, 1984.

In general conventional audio limiters can be characterized as being either the feedback type or the feed forward type. The feedback limiter is the more common type because its design is usually simpler and it provides better peak level control without a need for precise control of the loop gain of the limiter circuit.

The feed forward limiter is more common in applications where a thinned compression ratio is desired.

Mapes-Riordan, D. and Leach, W M JR, The design of a digital signal peak limiter for audio signal processing, J. Audio Eng. Soc., 36, 562, 1988 provides an overview of various limited techniques.

U.S. Pat. No. 5,631,969 shows a method for limiting the magnitude of an input signal where the input signal is sampled and transformed to obtain its component in-phase and quadrature components. The phasor magnitude of the signal sample is determined from those in-phase and quadrature components, and the input sample is limited based on the relationship of the phasor magnitude to a predetermined limit value. Specifically, the limiting step includes scaling the sample input signal using a ratio of the predetermined threshold to the phasor magnitude.

U.S. Pat. No. 4,754,230 shows a clipping suppression circuit for a communication system. The circuit includes a limiter peak detector for causing the gain of an input amplifier to be reduced when a compressed output is driven toward a clipping output condition.

U.S. Pat. No. 5,579,404 shows a digital to audio limiter. A signal processing system receives a peak-amplitude limited input audio signal, generates a processed audio signal in response to the input audio signal such that peak-level increase may be present, estimates the peak-level increase of the full-bandwidth processed audio signal, and generates an output audio signal by applying to the portion of the full-bandwidth subject to peak-level increase a gain factor adapted in response to the estimated peak amplitude.

U.S. Pat. No. 5,471,651 shows a system for compressing the dynamic rang of audio signals. An audio signal has its dynami9c range compressed by a system which first samples a block of the audio signal, typically several seconds long. The level of the signal in this block is analyzed and an ideal signal level is calculated for the block. A gain control signal is then derived which adjusts the gain applied to that block towards that required to give the calculated ideal signal level.

In essence three different methods of decreasing the dynamic range of program material have been used so far:

Compressors

Compressors, or dynamic-range compressors reduce the overall dynamic range of any program material. For example, if the original program material has a dynamic range of 90 dB, the dynamic range after processing is reduces to 40 dB for FM broadcasting, or 20 dB for AM broadcasting. The compressor consists of two elements: a level detector and an amplifier with a variable gain. The detector could be a peak detector or a root-mean-square detector including a certain temporal averager. The topology of compressors is either feed-forward or feed-backward. In the first case, the detected level of the level detector is converted to a gain value. The output signal then consists of the input signal multiplied by the gain value. Usually, the gain becomes smaller if the detected input level is larger. Consequently, high-level input signals are amplified less than low-level input signals, on the other hand, in feed-backward topologies the level detector is connected to the output of the compressor rather than the input. The conversion from the detected level to resulting gain describes the amount of compression, while the time constant of the level detector determines the temporal behavior of the compressor. More complex compressor designs include look-ahead features, variable attack and release times, soft-knee and hard-knee transitions and specification of the dynamic range the compressor should work on.

Clippers

Clippers are relatively simple applications: if the amplitude of the program material is beyond a certain limit, the output is clipped to the maximum output value. Hard clippers have no transition range: the amplitude is either clipped or it is not. Soft clippers have a certain transition range where the waveforms are non-linearly transformed in such a way that no hard edges occur in the waveforms.

Limiters

Limiters scan for peaks in the audio signal and attenuate the audio portion around the peak if the attenuation is necessary to prevent clipping. Associated with the attenuation curve are attack and release times. The attack time is the time that the limiter takes to respond to a peak, while the release time is the time that the limiter needs to restore to the original signal level (i.e., no attenuation).

The disadvantage of a clipper is obvious: the clipping process often causes unacceptable distortion of the program material. The disadvantages of limiters and compressors are related to their temporal behavior, in particular, the recovery or release time of these systems is subject to several conflicting requirements. By making the recovery time long compared to the time intervals between peaks in the signal, short transient peaks produce a prolonged gain reduction of the signal. This is heard as what is called a program “hole” or “dropout”. In addition, a long recovery time tends to decrease the power of the signal, a recovery time that is too short will not only cause increase signal distortion, especially for low-frequency in puts, but it also causes phenomena such as exaggeration of breath noises in speech, temporary reversal of the natural decay of sustained (piano) notes, a fluttering effect caused by random fluctuations in gain, and the fluctuation of otherwise continuous parts of the program material. The latter effects are commonly called “gain pumping”, “breathing” and “swishing”. Attempts to remedy these problems have involved the use of more than one recovery time constant and making the time constant inversely proportional to frequency.

It is therefore an object of the present invention to provide for an improved method of decreasing the dynamic range of a signal as well as a corresponding electronic circuit and computer program product.

### SUMMARY OF THE INVENTION

The invention provides for A method of decreasing the dynamic range of a signal comprising the steps of: determining a property of the signal, determining a limitation parameter (s) based on the property of the signal, limiting the signal by means of the limitation parameter, clipping the limited signal.

Preferred embodiments of the invention are given in the dependent claims.

Further the invention provides for an electronic circuit and a computer program for performing a method of the invention.

The present invention is particularly advantageous as it enables to clip a signal in a controlled manner, when the nature of the signal is such that clipping creates less orderable distortions in the program material in comparison to conventional limiting.

It is important to note the prior art solutions of dynamic range control focus on attenuation of the signal to prevent clipping and the resulting distortions. As a pose to this a point of departure of the present invention is the notion that for a specific class of signals, limiting results in less audible distortion of the program material than clipping, but for another class of signals, limiting results in more pronounced audible artifacts than clipping. For example, a pure sinusoid should never be clipped because the clipping process results in pronounced distortion products. Fast limiting, on the other hand, hardly results in audible modulations in pure tones, as long as the release time of the limiter is longer than the period of the tone. For very transient parts of the program material, such as onsets of percussion instruments, limiting harms the temporal structures (natural decay) of the transient and causes gain pumping of non-transient elements of the program material, if such a transient would be clipped the distortion products caused by the clipping process are often not audible because transients usually have a broadband spectrum and hence distortion products are masked by the program material itself.

Of course, many signals are not part of these extreme signal classes. To determine to what extent a signal should be limited or clipped, the “local crest factor” is introduced. This measure is defined as the peak value of a certain time slice of the signal, divided by the rms-value of that time slice. For a pure sinusoid, the local crest factor amounts to the square root of 2, while local peaks have much higher local crest factors.

If the local crest factor is small (square root of 2) clipping should be avoided, while larger values of the local crest factor indicate that more clipping may be introduced.

Since most compressors/limiters already contain algorithms to find local peaks and to compute the rms value of the certain time-slice of the audio signal, this process can very easily be implemented in any existing audio limiter. Furthermore, the computational complexity is overly simple.

In accordance with a preferred embodiment of the invention the property of the signal which determines the amount of limiting and clipping is determined by windowing the signal and determining the ratio of the signal maximum and the signal RMS value within that window. The higher this ratio is the more clipping is employed rather than limiting. This has the advantage that signal peaks are clipped rather than limited which minimizes the orderable distortion of the signal as such peaks have a broadband spectrum and hence distortion products caused by the clipping amazed by the signal itself.

In accordance with a further preferred embodiment of the invention the ratio of the signal maximum and the signal RMS value within the window is compared to the threshold. Preferably the threshold is the square root of two which is the ratio obtained for a sinusoid input signal. In this case no clipping is used and the operation of the limiter is not influenced by the ratio.

The present invention is advantageously employed for a variety of audio purposes:

Hearing Aids

In hearing aids, the signal which enters the hearing aid should be amplified as much as possible while keeping the occurrences of clipping minimal. Consequently, peaks in the audio signal limits the performance of the hearing aid and can be reduced in accordance with present invention.

Audio Coding

In lossy audio coding applications, strong transients and peak signals cause difficulties in the coding process. In this class of applications, the spectral and temporal characteristics of the quantization noise introduced by the audio codec depend on the audio signal to be coded. However, the update rate at which the spectral properties of the noise change is usually limited: the minimum audio frame length for which coding parameters are constant amounts to a few milliseconds. Consequently, coding of transients often results in pre-echos caused by the fact that the quantization noise is already adapted to the high transient level a few milliseconds before the actual transient. To reduce the audibility of the pre-echos, a relatively large number of bits have to be allocated to that specific audio frame. Because the number of bits determines the ratio between peak level of the signal and quantization noise, fewer bits have to be allocated if the peak is reduced in level in accordance with the present invention.

Record Industry

Especially popular music, the expression “louder is better” is becoming increasingly important. CDs are labeled “hot” if the loudness of the program material is evenly so. Products that have been introduced that increase the loudness of musical contents without increasing the maximum amplitude value are the SPL Loudness Maximizer, the TC Electronics Finalizer and the Waves Ultramaximizer. This is another field of application of the present invention.

### BRIEF DESCRIPTION OF THE DRAWINGS

Preferred embodiments of the invention are explained in the following in greater detail by making reference to the drawings in which:

FIG. 1 is illustrative of a flow chart of an embodiment for performing a method for decreasing the dynamic range of a signal,

FIG. 2 is a block diagram of a first embodiment of an electronic circuit in accordance with the invention,

FIG. 3 is a block diagram of an alternative embodiment.

### DETAILED DESCRIPTION

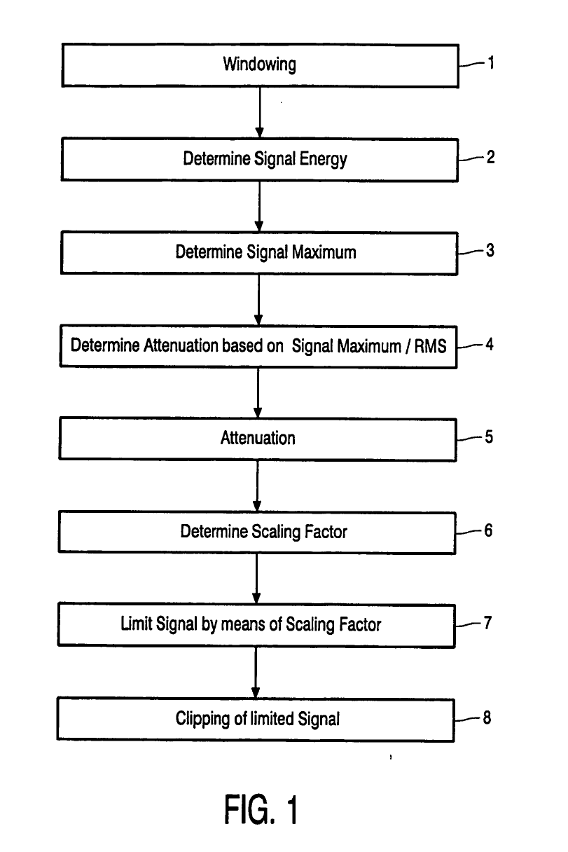

The flow chart of FIG. 1 illustrates the decreasing of the dynamic range of a signal. In step 1 the input signal is windowed. This means that for processing of the signal at a given point of time the signal is considered during a time window.

In step 2 the so-called RMS value of the signal within the window is determined. The RMS value is the square root of the power of the signal within the window.

In step 3 the maximum amplitude of the signal within the window is determined. In step 4 the ratio of the signal maximum determined in step 3 and the signal RMS value within the window as determined in step 2 is calculated. Based on this ratio a signal attenuation is determined. In case that the ratio or the so called “local crest factor” is relatively large; this means that the signal has a peak in the time window. The higher the peak in comparison to the rest of the signal within the window the higher the ratio. The ratio forms the bases to determine a signal attenuation as an input for the signal limitation. If the ratio is low no or little attenuation is selected. If the ratio is high a higher attenuation factor is selected. The attenuation serves to control the limiter such that a signal with a large peak is not limited as much as a signal with a lower peak as for a signal with a large peak clipping is more advantageous than limiting.

One way of controlling the limiter this way is to attenuate the signal maximum and provide the attenuated signal maximum to the limiter as a control parameter. This is done in step 5.

In step 6 the scaling factor for the limitation is determined based on the attenuated maximum as an input parameter.

In step 7 the original signal is limited by means of the scaling factor, i.e. by multiplying the actual signal value with the scaling factor. In case that the signal maximums had been attenuated to provide a corresponding input parameter to the limiter based on which the scaling factor is determined the output of the limiter may still exceed a maximum allowed signal level. This why the output of the limiter is clipped in step 8.

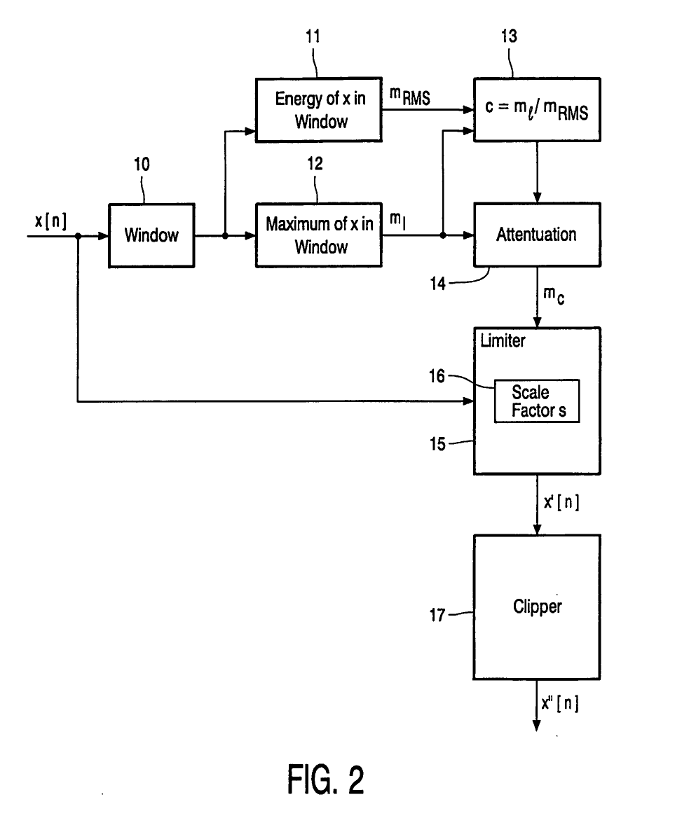

FIG. 2 shows a corresponding block diagram of an electronic circuit for decreasing the dynamic range. The input signal to be processed is inputted in the form of a discrete time domain signal x [n], where x [n] is the sampled waveform of x [nT] and T is the sampling period. For example the sampling frequency f_{S} is 44.1 kH.

x [n] must be limited to b bits in the digital domain. Hence, the maximum amplitude value M to represent x [n] is given by M=2^{b-1}. The purpose of the electronic circuit of FIG. 2 is to decrease the dynamic range of the signal x [n] such that it does not surpass the maximum amplitude value of M.

The signal x [n] is inputted into the filter 10 for windowing the signal x [n]. For example the time window applied to the signal x [n] is chosen in the order of 50 milliseconds. The filter 10 outputs the set of samples of the signal x within the window length.

These samples are inputted into the filter 11 for determination of the RMS value of the signal within the window. The RMS value is calculated by squaring and integrating the signal samples of the window in order to calculate m_{RMS}.

The set of samples which is outputted by the filter 10 is also inputted into the filter 12. The filter 12 serves to determine the maximum sample of the signal x within the window. The maximum sample within the window is denoted m₁.

The values m_{RMS} and m₁ are inputted into the processing unit 13 for calculation of the ratio c which equals m₁ divided by m_{RMS}. This ratio c is also called the “crest factor” as it is indicative of a property of the signal related to the maximum of the signal within the window and the RMS value of the signal within the window.

The ratio c is inputted into the attenuation unit 14 as a control parameter. Further the maximum m₁ is also inputted into the attenuation 14. The maximum m₁ is attenuated by the attenuation unit 14 in proportion to the ratio c. This attenuation serves to control the limiter 15 in order to decrease the amount of limiting performed by the limiter 15 for signals having high peaks and thus a high ratio c.

The attenuated maximum m_{c} is outputted by the attenuation unit 14 and in putted into the limiter 15 as a control parameter. Based on the attenuated maximum m_{c} a scale factor s is determined by the processing unit 16 within limiter 15. For example the scale factor s is chosen such that the input signal x [n] does not surpass a predetermined maximum M within the time window assuming that the attenuated maximum m_{c} is the real maximum for the purposes of the limitation.

The input signal x [n] is inputted into the limiter 15 and multiplied by the scale factor s. This creates the limited signal x′[n]. As the attenuated maximum m_{c} which serves as the basis for determining the scale factor s is not the real maximum but more or less below the real maximum the limited signal x′[n] still has one or more peaks which surpass the maximum M. This is why a clipping operation is performed on the limited signal x′[n] by means of the clipper 17. The clipper 17 outputs the signal x″[n]. The signal x″[n] has a dynamic range which does not surpass the maximum M.

To prevent clipping of signals which are closed a sinusoid it is advantageous to compare the ratio c with a threshold of √2. If the ratio is below the threshold the parameter c is chosen such that no attenuation is performed in the attenuation unit 14.

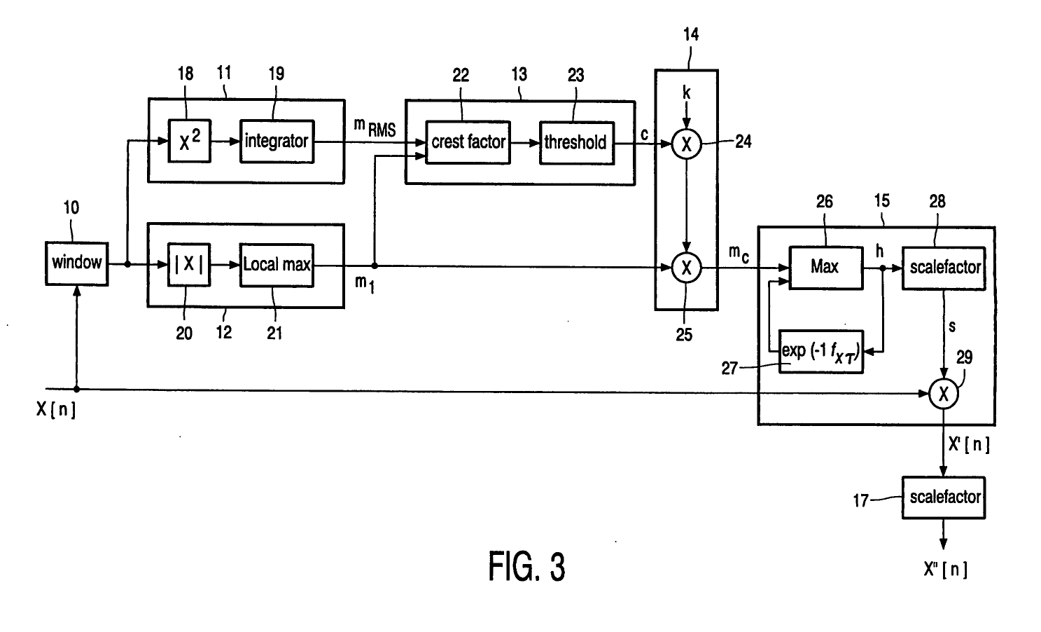

FIG. 3 shows an alternative embodiment of the circuit of FIG. 2. Elements of the circuit of FIG. 3 which corresponds to elements of the circuit of FIG. 2 are denoted by the same reference numerals.

In the circuit of FIG. 3 the filter 11 has a square unit 18 and an integrator 19 for calculation of m_{RMS}. The filter 12 has an unit 20 for determining the maximum value of the signal samples within the window and a unit 21 to determine the sample with the maximum peak m₁.

The processing unit 13 has an unit 22 in accordance with the following formula:

$$c = 20 log ( \frac{{m}_{i}}{{m}_{RMS}} ) - 3$$

In the following unit 23 of the processing unit 13 the ratio m₁/m_{RMS} is compared with the threshold of √2. If m₁/m_{RMS} is below √2 c is set to be equal to zero. Otherwise c remains unchanged. This thresholding operation ensures that no clipping is performed for sinusoid signals.

The attenuation unit 14 has a multiplier 24 for multiplying the ratio c by a correction-strength factor k. The factor k determines the amount of attenuation applied to the local maximum m₁ by the crest factor c. For k=0 no correction is applied and the limiter 15 behaves like a conventional limiter. For larger values of k the local maximum m₁ is reduces by the value determined by k and the crest factor c which applied by means of multiplier 25. The attenuated maximum m_{c} is given by
m_{c}=m₁10^{-kc/20}

A limiter 15 has an unit 26 for determining the maximum of the attenuated maximum m_{c} and the output of the unit 27. The output of the unit 26 is the maximum h which is inputted into the unit 27. The output h is multiplied by exp(−1/fₛτ), with τ the release time constant of the limiter.

In other words the attenuated maximum m_{c} is compared with the previous attenuated maximum multiplied by the exponential factor. From these two numbers, the maximum is taken as the current maximum of the waveform h. Hence, τ corresponds to the time constant that the limiter can release its attenuation.

The value of h is converted to the scale factor s within unit 28:

$$s = \{ \begin{matrix}1 & if h < M \\ M / h & if h \geq M\end{matrix}$$

where M is the maximum of the dynamic range.

The input signal x [n] is then multiplied by means of multiplier 29 within limiter 15 to produce a limited output signal x [n]. This is inputted into the clipper 17 to produce the signal x″ [n].

It is to be noted that both k and c have non-negative values. Hence, the attenuated maximum m_{c} is smaller or equal to the actual maximum m₁. If the attenuated maximum m_{c} is indeed smaller than the smaller actual maximum m₁ the clipper 17 clips the signal. Since this only happens for transients with a large bandwidth, distortion products associated with this clipping are not orderable.

Informal listening experiments demonstrated that an implementation with a value k of about 0.5 dB/dB, an analysis window length of 50 ms and a release time τ of 0.5 seconds performs significantly more transparent (i.e., no audible distortion products and significantly less pumping and breathing effects) than the conventional limiter (with k=0). Especially with critical source material (very peaky waveforms and program material with a deep bass content), the loudness and temporal behavior of transients are preserves better.

List of Reference Numerals

filter 10
filter 11
filter 12
processing unit 13
attenuation unit 14
limiter 15
processing unit 16
clipper 17
square unit 18
integrator 19
unit 20
unit 21
unit 22
unit 23
multiplier 24
multiplier 25
unit 26
unit 27
unit 28
multiplier 29

1. A method of decreasing the dynamic range of a signal comprising the steps of:
determining a property of the signal (c),
determining a limitation parameter (s) based on the property of the signal,
limiting the signal by means of the limitation parameter,
clipping the limited signal.

2. The method of claim 1 further comprising the following steps for determining the property of the signal:
windowing of the signal,
determining of the ratio of the signal maximum within the window and the signal RMS value within the window.

3. The method of claim 2, whereby no clipping is performed when the ratio is below a predefined threshold.

4. The method of claim 2 further comprising:
comparing the ratio to the threshold,
determining of the limitation parameter independently from the ratio if the ratio is below the threshold.

5. The method of claim 3, whereby the threshold is substantially equal to or above the ratio obtained for a sinusoid signal.

6. The method of claim 2, whereby the ratio is modified by a correction factor (K) and the limitation parameter is determined based on the modified ratio.

7. The method of claim 1 further comprising the following steps for determining the limitation parameter based on the property:
determining of the signal maximum within the window,
attenuation of the signal maximum in proportion to the ratio,
filtering of the attenuated maximum,
calculation of the limitation parameter by dividing the maximum (M) of the dynamic range by the filtered maximum, if the filtered maximum is above the maximum of the dynamic range.

8. An electronic circuit comprising means for performing a method in accordance with claim 1.

9. The electronic circuit of claim 8, whereby the electronic circuit is an audio circuit.

10. A computer program for performing a method in accordance with claim 1.
